(19) United States
(12) Patent Application Publication
(10) Pub. No.: US 2011/0215680 A1
(43) Pub. Date: Sep. 8, 2011

(54) RESONATOR ELEMENT, RESONATOR, OSCILLATOR, AND ELECTRONIC DEVICE

(75) Inventors: Akinori YAMADA, Ina (JP); Makoto FURUHATA, Matsumoto (JP)

(73) Assignee: SEIKO EPSON CORPORATION, Tokyo (JP)

(21) Appl. No.: 13/037,412

(22) Filed: Mar. 1, 2011

(30) Foreign Application Priority Data
Mar. 5, 2010 (JP) 2010-048832
Dec. 14, 2010 (JP) 2010-277757

(51) Int. Cl. H01L 41/04

(52) U.S. Cl. 310/370

(57) ABSTRACT

A resonator element includes: a base section; and at least one resonating arm formed so as to extend from the base section, and having a flexural vibrating section, wherein the flexural vibrating section includes a pair of principal surfaces formed along a direction in which the resonating arm performs a flexural vibration, and outer side surfaces intersecting with the principal surfaces of the resonating arm, the flexural vibrating section is provided with at least three groove sections, the groove sections are formed on both or either one of the principal surfaces in a direction intersecting with the principal surfaces, and at least a part or the whole of an outer wall formed of the outer side surface and the groove section and at least a part or the whole of an inner wall formed of the groove sections adjacent to each other are electrically vibrated in a flexural manner.

### BACKGROUND

1. Technical Field

The present invention relates to a resonator element having a resonating arm, a resonator or an oscillator provided with the resonator element, and an electronic device provided with these components.

2. Related Art

In the past, it has been known that if the flexural resonator element is miniaturized, the Q-value is reduced, and the flexural vibration is hindered. This is due to the thermoelastic effect caused when the frequency of the relaxation oscillation inversely proportional to the relaxation time until the thermal equilibrium is reached in response to the heat transfer and the vibrational frequency of the flexural resonator element come close to each other. Specifically, an elastic deformation is caused by the flexural vibration of the flexural resonator element, and the temperature of the surface contracted rises while the temperature of the surface expanded drops, and therefore, a temperature difference is caused inside the flexural resonator element. The temperature difference causes the heat conduction (heat transfer) for coming closer to thermal equilibrium, and therefore, the mechanically available energy is reduced to thereby deteriorate the Q-value.

Therefore, grooves or through holes are provided to the rectangular cross-sectional surface of the flexural resonator element to block the heat transfer caused between the surfaces of the resonator element in a direction from the surface to be contracted to the surface to be expanded, thereby achieving the prevention of the variation in the Q-value due to the thermoelastic effect (see, e.g., JP-UM-A-2-32229 (pp. 4-5, FIGS. 1-3) (Document 1)).

Further, according to “Analysis of Q-value of Quartz Crystal Tuning Fork Using Thermoelastic Coupling Equations” by Hideaki Itoh, Yuhya Tamaki, 36th EM symposium, pp. 5-8 (Document 2), the calculation of the Q-value is performed using the thermoelastic coupling equations with respect to one structural example of the quartz crystal tuning fork, and from the calculation result, it is reported that approximately 95% of the CI-value at 25° C. is due to the thermoelastic effect.

However, even if the related art described above is used, by providing the flexural vibrating section with through holes, a contracted surface and an expanded surface appear in each of the portions other than the through holes, and as a result, the Q-value is deteriorated. Further, even if the grooves of the flexural vibrating section are provided as described in Document 1, the effect on preventing the drop of the Q-value of the resonator element due to the thermoelastic effect is still insufficient. Therefore, in order for achieving the prevention of the drop of the Q-value due to the thermoelastic effect, there is room for further improvement, which is regarded as a problem. Further, since the CI-value is raised due to the deterioration of the Q-value by the thermoelastic effect, the improvement for decreasing the CI-value is also a problem concurrently therewith.

### SUMMARY

An advantage of some aspects of the invention is to solve at least a part of the problems described above and the invention can be implemented as the following embodiments application examples.

### Application Example 1

This application example of the invention is directed to a resonator element including a base section, and at least one resonating arm formed so as to extend from the base section, and having a flexural vibrating section performing a flexural vibration, wherein the flexural vibrating section includes a pair of principal surfaces formed along a direction in which the resonating arm performs the flexural vibration, and outer side surfaces intersecting with the principal surfaces of the resonating arm, the flexural vibrating section is provided with at least three groove sections, the groove sections are formed on both or either one of the principal surfaces in a direction intersecting with the principal surfaces, and at least a part or the whole of an outer wall formed of the outer side surface and the groove section the nearest to the outer side surface and at least a part or the whole of an inner wall formed of the groove sections adjacent to each other are electrically vibrated in a flexural manner.

According to this application example of the invention, by vibrating in a flexural manner the flexural vibrating section in the resonating arm provided with a plurality of walls (partition walls) formed of the grooves, the transfer path of the heat caused inside by the flexural deformation is elongated to thereby prevent the relaxation vibration hindering the flexural vibration, thus the deterioration of the Q-value due to the thermoelastic effect can be prevented. Further, since the substantial area of the excitation electrode can also be increased, the conversion efficiency between the mechanical system and the electrical system can be improved, and thus, the CI-value can also be prevented from rising.

### Application Example 2

This application example of the invention is directed to the resonator element of the above application example of the invention, wherein an opening section of one of the groove sections adjacent to each other and forming the inner wall is formed on one of the pair of principal surfaces, and an opening section of the other of the groove sections is formed on the other of the pair of principal surfaces, and the one of the pair of principal surfaces has at least one of the groove sections, and the other of the pair of principal surfaces has at least two of the groove sections.

According to this application example of the invention, since the heat transfer path can further be elongated, the thermal equilibrium time is further elongated, and it becomes possible to more strongly prevent the relaxation vibration.

### Application Example 3

This application example of the invention is directed to the resonator element of the above application example of the invention, wherein the groove sections adjacent to each other and forming the inner wall overlap each other at least partially in a direction intersecting with the principal surfaces.

According to this application example of the invention, since the heat transfer path can further be elongated, the prevention of the relaxation vibration can be enhanced, and at the same time, since the area of the excitation electrodes formed on the inner wall and the outer wall of the groove is increased, the conversion efficiency between the mechanical system and the electrical system with respect to the vibration can be enhanced to thereby reduce the CI-value.

### Application Example 4

This application example of the invention is directed to the resonator element of the above application example of the invention, wherein the resonator element is a tuning fork resonator element having the two resonating arms extending in parallel to each other from the base section.

According to this application example of the invention, a low-profile resonator element having a high Q-value, a low CI-value, and superior characteristics can be realized.

### Application Example 5

This application example of the invention is directed to the resonator element of the above application example of the invention, wherein the base section and the resonating arms are made of a piezoelectric material.

### Application Example 6

This application example of the invention is directed to the resonator element of the above application example of the invention, the piezoelectric material is a quartz crystal.

According to this application example of the invention, the low-profile resonator element superior in vibration characteristics can easily be obtained.

### Application Example 7

This application example of the invention is directed to a resonator including any one of the resonator elements described above, and a package adapted to house the resonator element.

### Application Example 8

This application example of the invention is directed to an oscillator including any one of the resonator elements described above, and a circuit section adapted to drive the resonator element.

According to this application example of the invention, the low-profile resonator and oscillator superior in vibration characteristics can be obtained.

### Application Example 9

This application example of the invention is directed to an electronic device including any one of the resonator elements described above, and a circuit section adapted to drive the resonator element.

According to this application example of the invention, an electronic device capable of continuously keeping the desired function can be provided.

### BRIEF DESCRIPTION OF THE DRAWINGS

The invention will be described with reference to the accompanying drawings, wherein like numbers reference like elements.

FIG. 1 is a perspective view of a resonator element according to a first embodiment of the invention.

FIGS. 2A and 2B are diagrams of the resonator element according to the first embodiment, wherein FIG. 2A is a plan view, and FIG. 2B is a cross-sectional view along the line A-A′ in FIG. 2A.

FIGS. 3A and 3B are diagrams showing electrodes provided to the resonator element according to the first embodiment, wherein FIG. 3A is a plan view, and FIG. 3B is a back plan view of FIG. 3A.

FIGS. 4A through 4C are cross-sectional views along the line P-P′, the line Q-Q′, and the line R-R′ in FIG. 3A, respectively.

FIG. 5 is an equivalent circuit diagram of the resonator element according to the invention.

FIG. 6 is a cross-sectional view showing another shape of the groove sections according to the first embodiment.

FIGS. 7A and 7B are cross-sectional views showing another shape of the groove sections according to the first embodiment.

FIGS. 8A and 8B are diagrams of a resonator according to a second embodiment of the invention, wherein FIG. 8A is a plan view, and FIG. 2B is a cross-sectional view along the line B-B′ in FIG. 8A.

FIG. 9 is a cross-sectional view of an oscillator according to a third embodiment of the invention.

FIG. 10 is a perspective view schematically showing a cellular phone as an example of an electronic device according to a fourth embodiment of the invention.

FIG. 11 is a block diagram of the cellular phone as an example of the electronic device according to the fourth embodiment.

FIG. 12 is a perspective view schematically showing a personal computer as an example of the electronic device according to the fourth embodiment.

### DESCRIPTION OF EXEMPLARY EMBODIMENTS

Hereinafter, an electronic device using the resonator element as an embodiment of the invention will be explained with reference to the accompanying drawings.

### First Embodiment

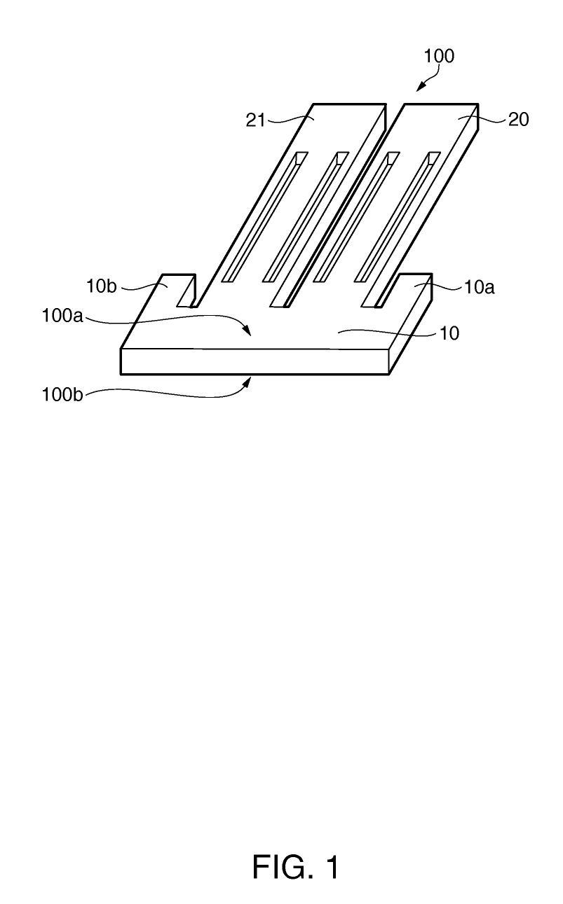

FIG. 1 is a schematic perspective view showing the first embodiment. As the material of a base section 10 of a resonator element 100 and resonating arms 20, 21 as vibrating sections, a piezoelectric material is preferable, and a quartz crystal among the piezoelectric material is further preferable. A piezoelectric material such as lithium tantalate (TiTaO₃), lithium tetraborate (Li₂B₄O₇), lithium niobate (LiNbO₃), lead zirconium titanate (PZT), zinc oxide (ZnO), aluminum nitride (AlN), or a semiconductor such as silicon (Si) can also be applicable. Hereinafter, the embodiment using the quartz crystal will be explained.

The resonator element 100 is formed of a quartz crystal substrate and has a shape of a so-called tuning fork type resonator element composed of a plate-like substrate having one principal surface 100a and the other principal surface 100b provided with the base section 10 and the resonating arms 20, 21. The base section 10 is further provided with support arms 10a, 10b extending therefrom separately from the resonating arms 20, 21.

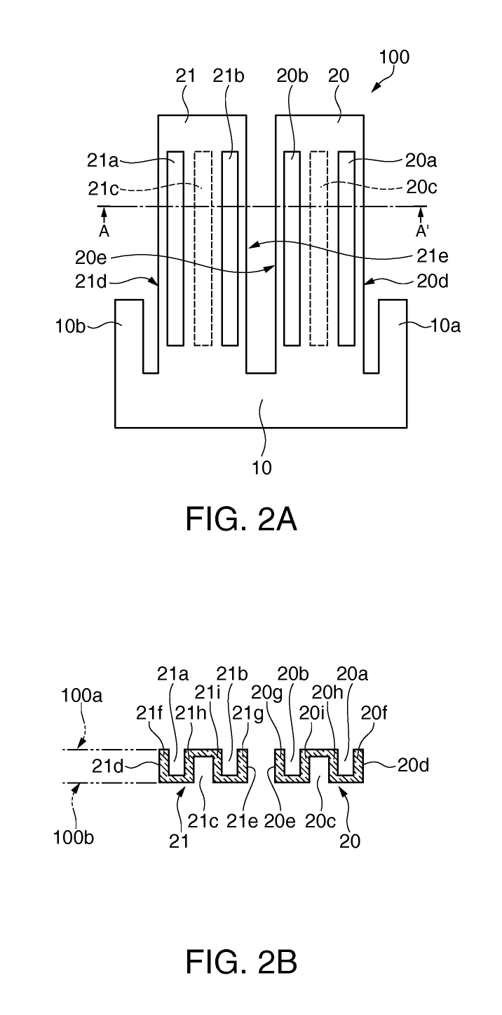

FIG. 2A shows a plan view of the resonator element 100, and FIG. 2B shows a cross-sectional view along the line A-A′ of FIG. 2A. As shown in FIG. 2B, the resonating arms 20, 21 are provided with grooves 20a, 20b, 21a, 21b formed on the side of the principal surface 100a, and are also provided with grooves 20c, 21c formed on the side of the other principal surface 100b. In the present embodiment, the two grooves 20a, 20b and 21a, 21b are provided to the respective resonating arms 20, 21 formed on the side of the principal surface 100a, and one groove 20c and 21c is provided to the respective resonating arms 20, 21 formed on the side of the other principal surface 100b.

An outer wall 20f is formed of an outer side surface 20d of the resonating arm 20 and the groove 20a. Here, the outer side surface is a designation for making it clear that this side surface is different from the inner wall and the outer wall as the side surfaces formed of the groove (the same will be applied below).

Similarly, an outer wall 20g is formed of an outer side surface 20e and the groove 20b. Further, inner walls 20h, 20i are formed of the grooves 20a, 20b, and 20c. Specifically, at least a part of the groove 20a and at least a part of the groove 20c are disposed so as to overlap each other with respect to the direction intersecting with or perpendicular to the principal surfaces 100a, 100b, thereby forming the inner wall 20h. In order for forming the inner wall 20h in the manner as described above, it is sufficient to set the sum of the depth of the groove 20a and the depth of the groove 20c to be larger than the distance between the principal surface 100a and the principal surface 100b. At least a part of the groove 20b and at least a part of the groove 20c are disposed so as to overlap each other with respect to the direction intersecting with or perpendicular to the principal surfaces 100a, 100b, thereby forming the inner wall 20i. In order for forming the inner wall 20h in the manner as described above, it is sufficient to set the sum of the depth of the groove 20b and the depth of the groove 20c to be larger than the distance between the principal surface 100a and the principal surface 100b. It should be noted that the depth of each of the grooves 20a, 20b, and 20c is set to be smaller than the distance between the principal surface 100a and the principal surface 100b. The resonating arm 21 is also provided with the outer walls 21f, 21g and the inner walls 21h, 21i formed in the same manner as in the case of the resonating arm 20.

Although not shown in FIG. 2B, excitation electrodes for causing the flexural vibration in the resonating arms 20, 21 described later are formed on the outer walls 20f, 20g and the inner walls 20h, 20i of the resonating arm 20, and the outer walls 21f, 21g and the inner walls 21h, 21i of the resonating arm 21. By making a current flow through the excitation electrodes thus formed to thereby alternately contract the outer walls 20f, 20g, 21f, 21g and the inner walls 20h, 20i, 21h, 21i, an excitation section for causing the flexural vibration in the resonating arms 20, 21 is constituted.

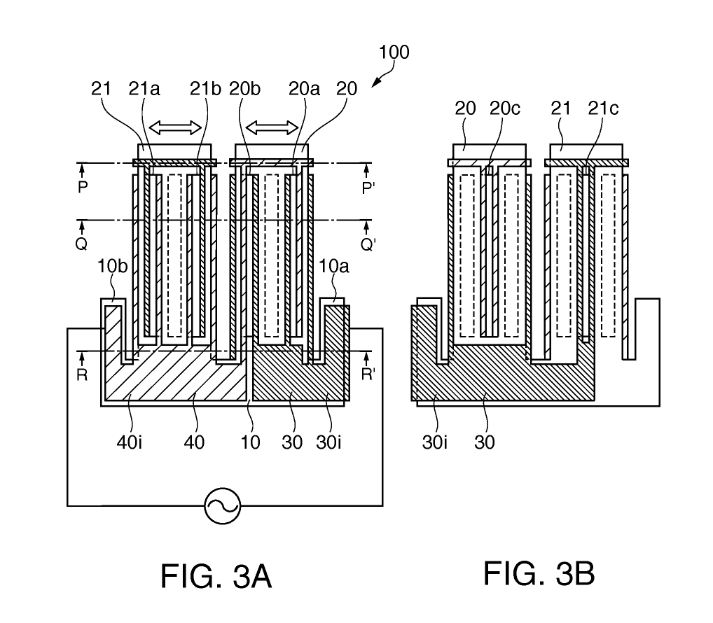

FIGS. 3A and 3B are diagrams schematically showing the electrode wiring provided to the resonator element 100, wherein FIG. 3B shows the plan view thereof viewed from the back side with respect to the plan view of FIG. 3A. It should be noted that in the explanation described hereinafter, the surface shown in FIG. 3A is denoted as an obverse side and the surface shown in FIG. 3B is denoted as a reverse side for the sake of convenience. As shown in FIGS. 3A and 3B, the obverse and reverse surfaces of the resonator element 100 are provided with an electrode 30 and an electrode 40, and an alternating current is applied to the electrode 30 and the electrode 40 from an oscillation circuit not shown, and thus the resonating arms 20, 21 perform the flexural vibration.

The electrodes 30, 40 are electrically connected to external connection terminals not shown on the obverse surface when mounting the resonator element 100, and laid around to the base section 10 including the support arms 10a, 10b to be fixed to thereby form base section electrodes 30i, 40i. Further, the base section electrode 30i provided to the base section 10 extends via the side surface section of the base section 10 to form the base section electrode 30i on the reverse surface. The electrodes extend from the base section electrodes 30i, 40i to the grooves of the resonating arms 20, 21 to be the excitation section.

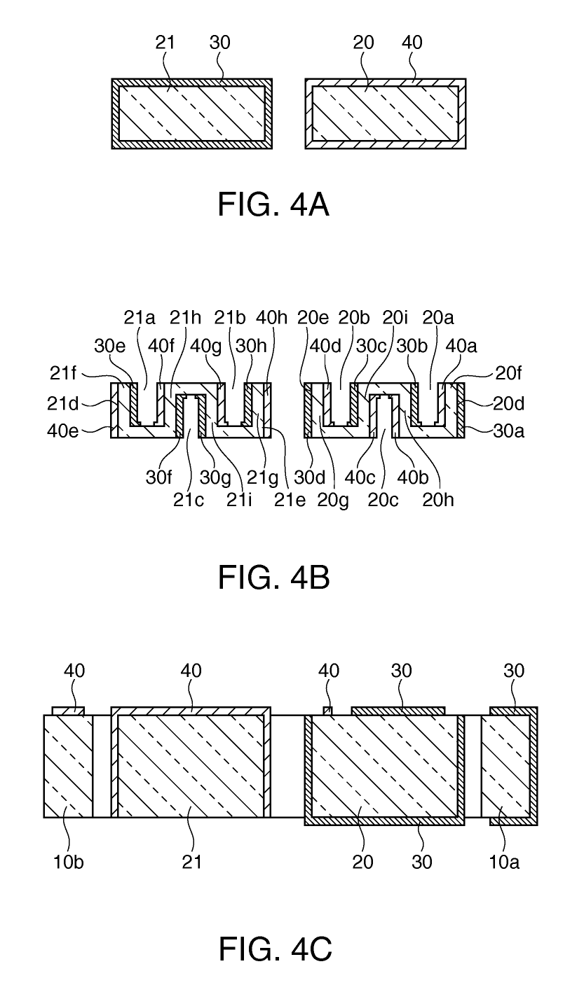

Then, an electrode film will be explained with reference to FIGS. 4A through 4C showing the Q-Q′ cross-section including the grooves shown in FIG. 3A. Firstly, the resonating arm 20 will be explained. The grooves 20a, 20b are formed on the obverse surface of the resonating arm 20, and the groove 20c is formed on the reverse surface thereof. The outer walls 20f, 20g and the inner walls 20h, 20i are formed of the grooves 20a, 20b, and 20c and the outer side surfaces 20d, 20e of the resonating arm 20. The electrodes 30, 40 are wired along the wall surfaces of the outer walls 20f, 20g and the inner walls 20h, 20i.

In the outer wall 20f, the excitation electrode 30a is formed in the portion of the outer side surface 20d, and the excitation electrode 40a is formed in the portion of the groove 20a. In the inner wall 20h, the excitation electrode 30b is formed in the portion of the groove 20a, and the excitation electrode 40b is formed in the portion of the groove 20c. In the inner wall 20i, the excitation electrode 40c is formed in the portion of the groove 20c, and the excitation electrode 30c is formed in the portion of the groove 20b. In the outer wall 20g, the excitation electrode 40d is formed in the portion of the groove 20b, and the excitation electrode 30d is formed in the portion of the outer side surface 20e.

Here, when the current is applied to the electrodes 30, 40, the electrical fields in the same direction are generated in the outer wall 20f and the inner wall 20h provided with the excitation electrodes 30a, 40a and the excitation electrodes 30b, 40b, respectively. Further, the electrical fields having the directions, which are identical to each other and opposite to the directions of the electrical fields in the outer wall 20f and the inner wall 20h, are generated in the outer wall 20g and the inner wall 20i provided with the excitation electrodes 30d, 40d, and the excitation electrodes 30c, 40c, respectively. Therefore, in the case, for example, in which the electrical fields in the direction of expanding the outer wall 20f and the inner wall 20h are generated inside the outer wall 20f and the inner wall 20h, the electrical fields in the reverse direction of contraction are generated inside the outer wall 20g and the inner wall 20i, and in the case in which the electrical fields in the direction of contracting the outer wall 20f and the inner wall 20h are generated inside the outer wall 20f and the inner wall 20h, the electrical fields in the reverse direction of expansion are generated inside the outer wall 20g and the inner wall 20i. By repeating these actions alternately, the resonating arm 20 repeats the flexural vibration in the direction indicated by the arrow illustrated at the tip of the resonating arm 20 in FIG. 3A.

Similarly, the resonating arm 21 will be explained. In the resonating arm 21, the electrodes 30, 40 are raid around so that the electrical fields in the same direction are generated in the outer wall 21f and the inner wall 21h, and the electrical fields having the directions, which are identical to each other and opposite to the direction of the electrical fields generated in the outer wall 21f and the inner wall 21h, are generated in the outer wall 21g and the inner wall 21i. Therefore, in the case, for example, in which the electrical fields in the direction of expanding the outer wall 21f and the inner wall 21h are generated inside the outer wall 21f and the inner wall 21h, the electrical fields in the reverse direction of contraction are generated inside the outer wall 21g and the inner wall 21i. In the case in which the electrical fields in the direction of contracting the outer wall 21f and the inner wall 21h are generated inside the outer wall 21f and the inner wall 21h, the electrical fields in the reverse direction of expansion are generated inside the outer wall 21g and the inner wall 21i. By repeating these actions alternately, the resonating arm 21 repeats the flexural vibration in the direction indicated by the arrow illustrated at the tip of the resonating arm 21 in FIG. 3A.

Further, there is provided the electrode wiring of generating the electrical fields in the same direction in the outer wall 20f and the inner wall 20h of the resonating arm 20 and the outer wall 21f and the inner wall 21h of the resonating arm 21. Further, there is provided the electrode wiring of generating the electrical fields in the outer wall 20g and the inner wall 20i of the resonating arm 20 and the outer wall 21g and the inner wall 21i of the resonating arm 21 having the directions identical to each other and opposite to the direction of the electrical fields generated in the outer wall 20f and the inner wall 20h of the resonating arm 20 and the outer wall 21f and the inner wall 21h of the resonating arm 21. Thus, the resonating arm 20 and the resonating arm 21 perform the flexural vibration as the tuning fork type resonator element in which the tip portions thereof repeat approaching and separating to/from each other.

As described above, by electrically causing the flexural vibration in each of the walls of the flexural vibrating section provided to each of the resonating arms 20, 21 to cause expansion and contraction, the resonating arms 20, 21 perform the flexural vibration. On this occasion, in each of the wall surfaces of the walls, the temperature of the wall surface rises when the wall contracts, and the temperature of the wall surface drops when the wall expands. In the case of the resonating arm 20, when, for example, the outer wall 20f and the inner wall 20h expand while the outer wall 20g and inner wall 20i contract, the temperature of the outer wall 20f and the inner wall 20h rises while the temperature of the outer wall 20g and the inner wall 20i drops. Therefore, there is caused a temperature difference between the outer wall 20f, the inner wall 20h and the outer wall 20g, the inner wall 20i. The temperature difference causes the heat conduction (heat transfer) for coming closer to thermal equilibrium, and therefore, the mechanically available energy is reduced to thereby deteriorate the Q-value. Further, the closer the frequency of the flexural vibration and the relaxation frequency fo inversely proportional to the relaxation time τo until the thermal equilibrium is approximately reached are, the more significantly the Q-value is deteriorated. Here, the relationship between the relaxation frequency fo and the relaxation time τo is expressed as fo=1/(2πτo).

By forming the flexural vibrating section of each of the resonating arms 20, 21 with a plurality of walls to thereby elongate the heat transfer path of the vibrating section, the relaxation time τ is also elongated. Therefore, it results that the relaxation frequency fo is made further from the flexural vibration frequency, and thus the deterioration of the Q-value due to the thermoelastic effect can be prevented.

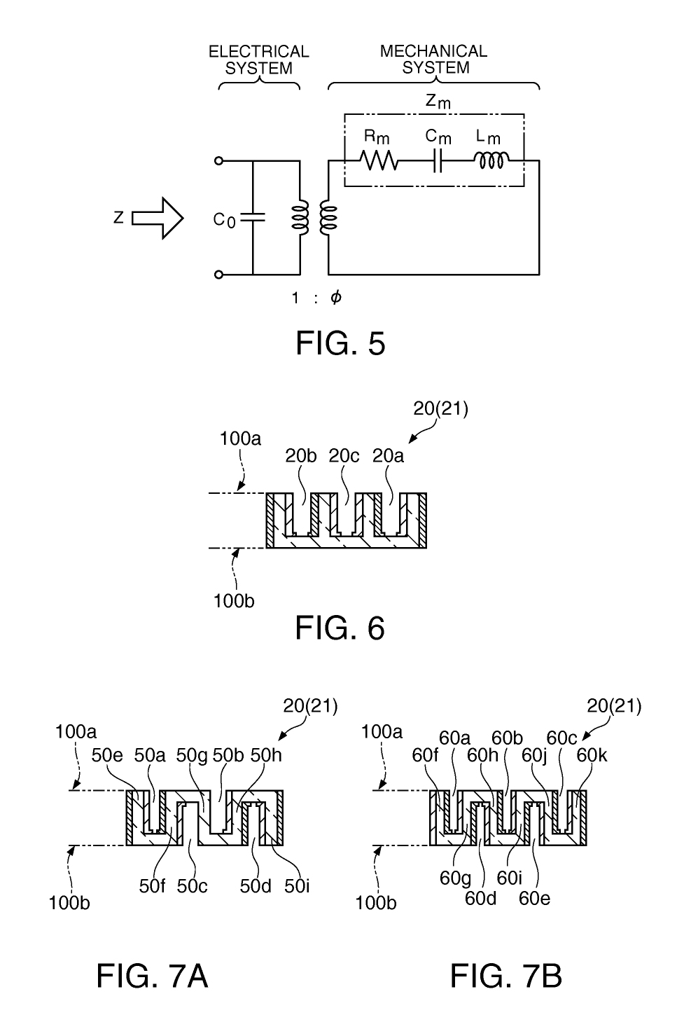

Further, according to the resonator element related to the invention, since the area of the excitation electrode can substantially be increased, it is possible to improve the conversion efficiency between the mechanical system and the electrical system with respect to the vibration. Specifically, as shown in the equivalent circuit of FIG. 5, the resistance value of the mechanical system as an input impedance Z to the electrical system from the left side in FIG. 5, namely the CI-value, is expressed as Rm/Φ₂ (Φ denotes the conversion efficiency between the mechanical system and the electrical system), and since the conversion efficiency Φ can be improved, the CI-value can be reduced.

It should be noted that although explained above as the resonator element in the flexural vibration mode, even if the resonator element mainly having the flexural vibration mode and including another vibration mode such as the torsional vibration mode is adopted, it is possible to obtain the resonator element having the advantages the same as above, namely the prevention of the deterioration of the Q-value and the high CI-value.

It should be noted that although in the present embodiment, regarding the arrangement of the grooves, there is explained the configuration in which the two grooves 20a, 20b are formed on the side of the principal surface 100a of the resonating arm 20 of the resonator element 100, the two grooves 21a, 21b are formed on the side of the principal surface 100a of the resonating arm 21, and the grooves 20c, 21c are formed on the side of the other principal surface 100b of the respective resonating arms, the configuration in which one groove is formed on the obverse surface of either one of the resonating arms 20, 21, and two grooves are formed on the side of the reverse surface thereof can also be adopted.

Further, although the excitation electrodes 40b, 40c and the excitation electrodes 30f, 30g respectively provided to the grooves 20c, 21c, which are the central grooves of the respective resonating arms 20, 21, are separated on the bottoms of the grooves, the excitation electrodes 40b, 40c and the excitation electrodes 30f, 30g are the excitation electrodes through which the in-phase current flows, and therefore, can be connected to each other on the respective bottoms of the grooves. Further, by making the excitation electrodes continuously, it is possible to make the formation of the electrodes easier.

It should be noted that the arrangement of the grooves provided to the resonating arms 20, 21 can be modified so that the openings of the respective grooves 20a, 20b, and 20c are disposed only on the side of either one of the principal surfaces, for example, on the side of the principal surface 100a in FIG. 6, as the cross-sectional shape of the groove sections of the resonating arms 20, 21 shown in FIG. 6. Further, although not shown in the drawings, it is also possible that the openings of the grooves of the other resonating arm 21 are disposed on the same side as those of the one resonating arm 20, or on the side of the other principal surface 100b.

FIGS. 7A and 7B are cross-sectional views showing other examples of the configuration of the formation of the grooves and walls provided to the flexural vibrating section. FIGS. 7A and 7B show the resonator elements with other configurations, corresponding to the cross-sectional shape at the position of the Q-Q′ cross-section in FIG. 3A. The resonator element shown in FIG. 7A is provided with two grooves 50a, 50b formed on the side of the principal surface 100a of each of the resonating arms 20, 21, and two grooves 50c, 50d formed on the side of the other principal surface 100b thereof, thus the five walls are formed. On this occasion, the electrodes 30, 40 are provided to the outer walls 50e, 50i, and the inner walls 50f, 50h. The inner wall 50g at the central portion is formed at the central portion of each of the resonating arms 20, 21, and is therefore the wall having no contribution to the flexural vibration of the resonating arms 20, 21. Therefore, the inner wall 50g is not provided with the electrodes 30, 40.

The resonator element shown in FIG. 7B is provided with three grooves 60a, 60b, and 60c formed on the side of the principal surface 100a of each of the resonating arms 20, 21, and two grooves 60d, 60e formed on the side of the other principal surface 100b thereof, thus the six walls are formed. On this occasion, the electrodes 30, 40 are provided to the outer walls 60f, 60k, and the inner walls 60g, 60h, and 60i.

According to the configuration explained with reference to FIGS. 7A and 7B described above, in the grooves according to the invention, by providing two or more grooves to one surface of the resonating arm, and one or more grooves to the other surface thereof, the resonator element having the Q-value prevented from being deteriorated and the high CI-value can be realized.

### Second Embodiment

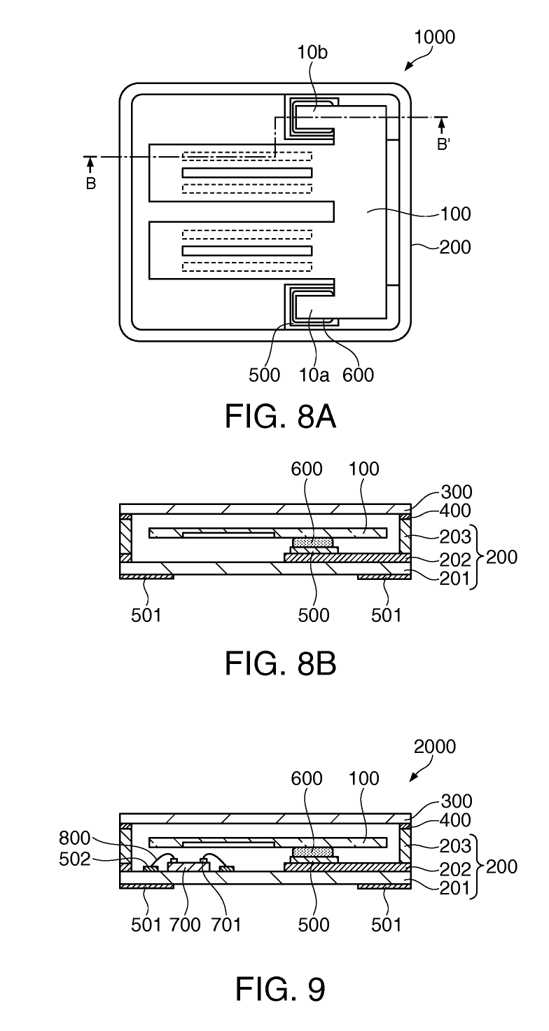

A resonator using the resonator element 100 according to the first embodiment described above will be explained. FIG. 8A is a plan view of the resonator 1000 in the condition in which a lid member is removed to expose the inside thereof, and FIG. 8B is a cross-sectional view showing the cross-section along the line B-B′ in FIG. 8A. The resonator element 100 is disposed in a package 200 composed of a first substrate 201, a second substrate 202, and a third substrate 203 stacked one another and is fixed to the package 200 with the electrodes 30, 40 of the support arms 10a, 10b of the resonator element 100 opposed to an electrode sections 500 formed on the second substrate 202 and electrically connected thereto with an electrically conductive adhesive 600. The electrode sections 500 pass through paths not shown inside the package 200, and are connected to mounting terminals 501 formed outside the package 200.

The lid member 300 is fixed to an edge portion of the opening of the package 200, to which the resonator element 100 is fixed, with a sealant 400 in a low-pressure chamber, and the inside of the resonator 1000 is kept in a low-pressure condition. The resonator 1000 thus obtained can make the resonator element 100 perform the flexural vibration with an alternating current supplied from an oscillation circuit not shown via the mounting terminals 501.

By applying the resonator element 100 according to the first embodiment to the resonator 1000, the resonator having the Q-value prevented from being deteriorated and the high CI-value can be obtained.

### Third Embodiment

As a third embodiment, an oscillator using the resonator element 100 according to the first embodiment described above will be explained. FIG. 9 is across-sectional view showing the oscillator 2000 according to the third embodiment. Since the present embodiment is different from the resonator 1000 described above only in the point of providing an IC chip including a drive circuit for driving the resonator element 100, the explanation of the constituents substantially the same as those of the resonator 1000 will be omitted, and the same constituents are provided with the same reference symbols.

As shown in FIG. 9, the oscillator 2000 has the resonator element 100 fixed to the electrode sections 500 disposed on the second substrate 202 inside the package 200. Further, an IC chip 700 is fixed to the first substrate 201 with an adhesive or the like, and an IC connection pads 701 formed on the upper surface of the IC chip 700 and internal connection terminals 502 formed on the first substrate 201 are electrically connected to each other with metal wires 800.

By applying the resonator element 100 according to the first embodiment, the oscillator having the Q-value prevented from being deteriorated and the high CI-value can be obtained.

### Fourth Embodiment

As a fourth embodiment, an electronic device having the resonator element 100 according to the first embodiment, and a circuit section for driving the resonator element 100 will be explained.

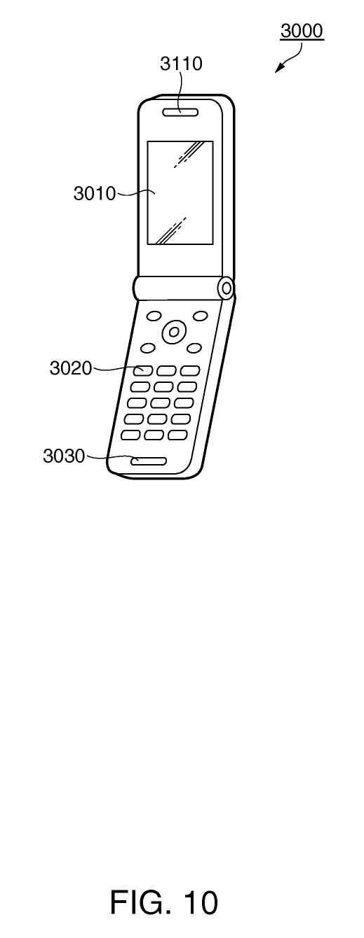

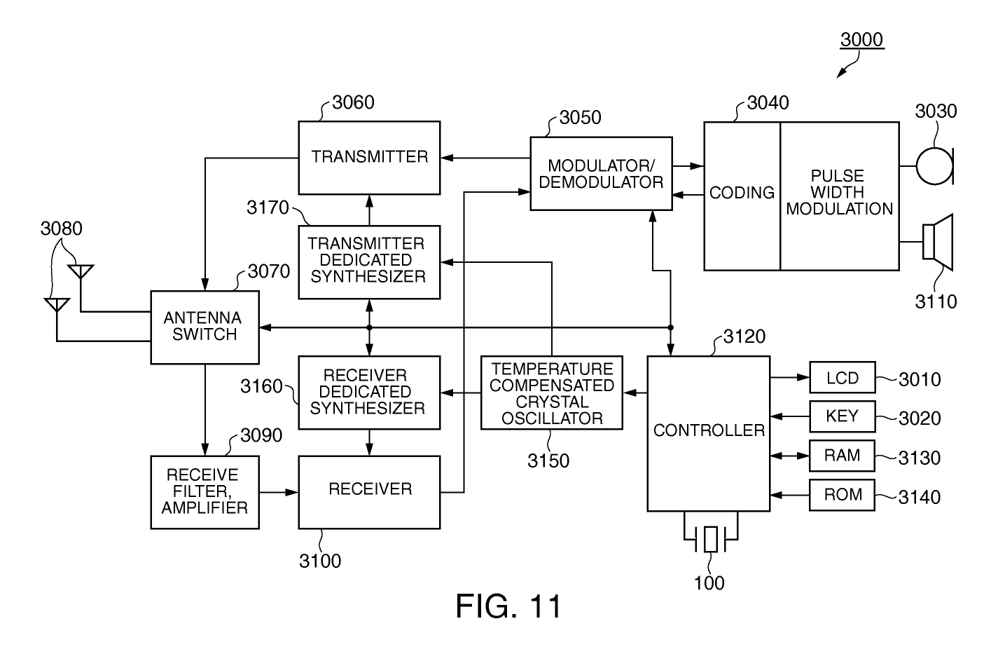

FIGS. 10 and 11 show a cellular phone as an example of the electronic device according to the fourth embodiment. FIG. 10 is a perspective view showing a schematic appearance of the cellular phone, and FIG. 11 is a circuit block diagram for explaining a circuit section of the cellular phone.

The resonator element 100 described above can be used in the cellular phone 3000. The explanation of the configuration and the operation of the resonator element 100 will be omitted by using the same reference symbols.

As shown in FIG. 10, the cellular phone 3000 is provided with a liquid crystal display (LCD) 3010 as the display section, keys 3020 as an input section of the numerical characters and so on, a microphone 3030, a speaker 3110, a circuit section not shown, and so on.

As shown in FIG. 11, in the case of performing the transmission in the cellular phone 3000, when the user inputs his or her voice to the microphone 3030, it results that the signal passes through the pulse width modulation/coding block 3040 and the modulator/demodulator block 3050, and further passes through a transmitter 3060 and an antenna switch 3070, and is then transmitted from the antenna 3080.

Incidentally, a signal transmitted from a cellular phone of another person is received by the antenna 3080, and then input from a receiver 3100 to the modulator/demodulator block 3050 via the antenna switch 3070 and a receive filter 3090. Further, it is arranged that the signal modulated or demodulated passes through the pulse width modulation/coding block 3040, and is then output from the speaker 3110 as a voice.

There is provided a controller 3120 for controlling the antenna switch 3070, the modulator/demodulator block 3050, and so on among these constituents.

The controller 3120 also controls the LCD 3010 as the display section, the keys 3020 as the input section for the numerical characters and so on, and further a RAM 3130, a ROM 3140, and so on besides the constituents described above, and is therefore required to be highly accurate. Further, downsizing of the cellular phone 3000 is also required.

As the device corresponding to such a requirement, the resonator element 100 described above is used.

It should be noted that although the cellular phone 3000 is also provided with a temperature compensated crystal oscillator 3150, a receiver dedicated synthesizer 3160, a transmitter dedicated synthesizer 3170, and so on as additional constituent blocks, the explanation therefor will be omitted.

Since the resonator element 100 described above used in the cellular phone 3000 has the flexural vibrating section of the resonating arms 20, 21 formed of a plurality of walls, the deterioration of the Q-value due to the thermoelastic effect can be prevented, and the CI-value can be reduced. Therefore further downsizing is possible while keeping the vibration characteristics. Therefore, the electronic device using this resonator element becomes capable of continuously keeping the function as the electronic device.

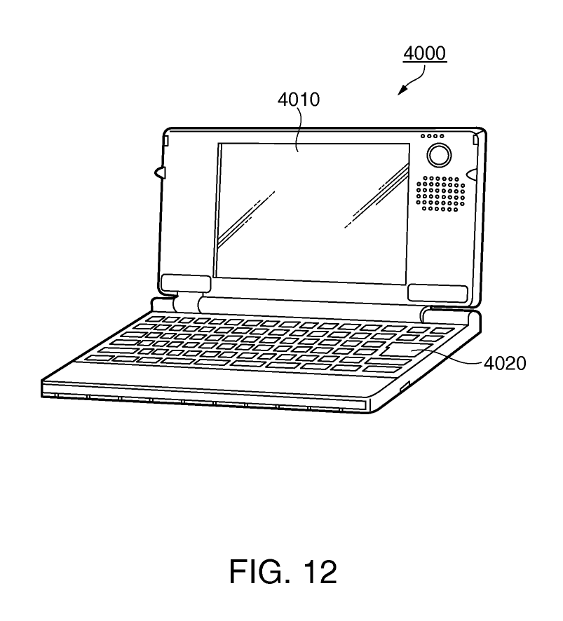

As the electronic device according to the invention, there can also be cited a personal computer (a mobile personal computer) 4000 shown in FIG. 12. The personal computer 4000 is provided with a display section 4010, an input key section 4020, and so on, and the resonator element 100 described above is used as the reference clock for electrical control therefor.

Further, as the electronic device provided with the resonator element 100 according to the invention, there can be cited in addition to the devices described above, for example, a digital still camera, an inkjet ejection device (e.g., an inkjet printer), a laptop personal computer, a television set, a video camera, a video cassette recorder, a car navigation system, a pager, a personal digital assistance (including one with communication function), an electronic dictionary, an electric calculator, a computerized game machine, a word processor, a workstation, a video phone, a security video monitor, a pair of electronic binoculars, a POS terminal, a medical device (e.g., an electronic thermometer, an electronic manometer, an electronic blood sugar meter, an electrocardiogram measurement instrument, an ultrasonograph, and an electronic endoscope), a fish detector, various types of measurement instruments, various types of gauges (e.g., gauges for a vehicle, an aircraft, or a ship), and a flight simulator.

Although the resonator element, the resonator, the oscillator, and the electronic device according to the invention are explained based on the embodiments shown in the accompanying drawings, the present invention is not limited to these embodiments, but the configuration of each of the components can be replaced with one having an identical function and any configuration. Further, it is possible to add any other constituents to the invention. Further, the apparatus according to the invention can be a combination of any two or more configurations (features) out of the embodiments described above.

For example, although in the embodiments described above the case in which the resonator element has the two resonating arms as the vibrating sections is explained as an example, the number of resonating arms can also be three or larger.

Further, the resonator element explained in the embodiments described above can also be applied to a gyro sensor or the like besides the piezoelectric oscillators such as a voltage controlled crystal oscillator (VCXO), a temperature compensated crystal oscillator (TCXO), and an oven controlled crystal oscillator (OCXO).

The entire disclosure of Japanese Patent Application Nos: 2010-048832, filed Mar. 5, 2010 and 2010-277757, filed Dec. 14, 2010 are expressly incorporated by reference herein.

1. A resonator element comprising:
a base section; and
at least one resonating arm formed so as to extend from the base section, and having a flexural vibrating section performing a flexural vibration,
wherein the flexural vibrating section includes a pair of principal surfaces formed along a direction in which the resonating arm performs the flexural vibration, and outer side surfaces intersecting with the principal surfaces of the resonating arm,
the flexural vibrating section is provided with at least three groove sections,
the groove sections are formed on both or either one of the principal surfaces in a direction intersecting with the principal surfaces, and
at least a part or the whole of an outer wall formed of the outer side surface and the groove section the nearest to the outer side surface and at least a part or the whole of an inner wall formed of the groove sections adjacent to each other are electrically vibrated in a flexural manner.

2. The resonator element according to claim 1, wherein
an opening section of one of the groove sections adjacent to each other and forming the inner wall is formed on one of the pair of principal surfaces, and an opening section of the other of the groove sections is formed on the other of the pair of principal surfaces, and
the one of the pair of principal surfaces has at least one of the groove sections, and the other of the pair of principal surfaces has at least two of the groove sections.

3. The resonator element according to claim 2, wherein
the groove sections adjacent to each other and forming the inner wall overlap each other at least partially in a direction intersecting with the principal surfaces.

4. The resonator element according to claim 3, wherein
the resonator element is a tuning fork resonator element having the two resonating arms extending in parallel to each other from the base section.

5. The resonator element according to claim 4, wherein
the base section and the resonating arms are made of a piezoelectric material.

6. The resonator element according to claim 5, wherein
the piezoelectric material is a quartz crystal.

7. A resonator comprising:
the resonator element according to claim 1; and
a package adapted to house the resonator element.

8. An oscillator comprising:
the resonator element according to claim 1; and
a circuit section adapted to drive the resonator element.

9. An electronic device comprising:
the resonator element according to claim 1; and
a circuit section adapted to drive the resonator element.
